(19) United States
(12) Patent Application Publication
(10) Pub. No.: US 2022/0148341 A1
(43) Pub. Date: May 12, 2022

(54) 12V BATTERY END OF LIFE PREDICTION WITH CONNECTED SERVICES

(71) Applicant: Robert Bosch GmbH, Stuttgart (DE)

(72) Inventors: Pascal Stephan Martin, Fenton, MI (US); Troy Schilling, Brighton, MI (US); Juergen Motz, Steinheim (DE); Clemens Hermann Schmucker, Tamm (DE); Oliver Dieter Koller, Weinstadt (DE); Frederic Heidinger, Esslingen (DE)

(21) Appl. No.: 17/094,418

(22) Filed: Nov. 10, 2020

(51) Int. Cl. G07C 5/00; G01R 31/367; G01R 31/389; G01R 31/371

(52) U.S. Cl. CPC G07C 5/006; G07C 5/008; G01R 31/371; G01R 31/389; G01R 31/367

(57) ABSTRACT

In a number of embodiments, mathematical certainty and confidence to the prediction of battery failure due to a predicted future temperature drop is provided. A connected service may be used by a vehicle to obtain an accurate temperature forecast that will help predict a discrepancy between needed and available cold cranking amps to start a vehicle engine. If a determination is made, based at least upon a temperature forecast and battery health, that the battery will yield insufficient cranking amps to start a vehicle engine in the near future and may not be sufficiently rechargeable, a recommendation that the battery be replaced may be made in advance of the battery's end of life.

### FIELD

Embodiments relate to predicting the end of life of a vehicle battery.

### BACKGROUND

Passenger and similar vehicles use batteries for a number of reasons. Often, a battery is used to power an electric starter motor to start or “crank” an internal combustion engine of a vehicle.

To “crank” a vehicle's internal combustion engine, a vehicle battery should deliver a sufficient amount of cranking amperage or voltage to a starter motor. The amperage or voltage must be sufficient to cause the starter motor to produce an amount of torque needed to mechanically drive a fly wheel and crankshaft to begin a fuel intake combustion process. Often, a battery used for cranking the vehicle internal combustion engine is positioned in an area of the vehicle that is largely exposed to the elements. When a vehicle is stored in an area that is not climate controlled, the vehicle battery is exposed to various temperature conditions, including low temperature conditions (for example, temperatures lower than 32° Fahrenheit). If temperatures are low enough, the vehicle battery may be chilled, lose charge, and be unable to provide requisite amperage or voltage to the starter motor. On, for example, a cold morning, a driver of a vehicle may be upset to find that her vehicle will not start due to the vehicle battery being incapable of delivering sufficient amperage or voltage to the starter motor.

In cases in which the vehicle battery's state of health is good, a recharge of the vehicle battery may be sufficient to return the battery to proper functioning. However, if a vehicle battery's health has degraded to a point at which the battery is no longer capable of storing a charge required to deliver a sufficient amount of amperage or voltage to a vehicle motor, the battery should be replaced.

### SUMMARY

Accordingly, embodiments provide methods and systems for, among other things, predicting an end of the operational life (or end of life) of a vehicle battery due to the combination of a drop in battery temperature and an increase in an internal impedance due to an aging of the battery. The methods and systems herein also notify a key user or driver of the vehicle that the battery must be replaced.

One embodiment provides a vehicle battery failure estimator that includes an electronic processor configured to produce a model of a vehicle battery in the form of state variables and model parameters. The electronic processor is also configured to receive a temperature forecast from a connected service and to predict an end of life of the vehicle battery based upon the model of the battery and the temperature forecast. In the case of a predicted end of life, the electronic processor notifies a user via the connected service that the vehicle battery should be replaced.

In another embodiment, a method of predicting an end of life of a vehicle battery is provided. In this embodiment, the vehicle battery is constructed and arranged to deliver a required amount of cranking amperage to a starter motor of a vehicle. An end of life occurs when the vehicle battery is incapable of maintaining enough charge to deliver a required amount of cranking amperage to the starter motor of the vehicle. The method includes using an electronic sensor to determine an internal impedance for a vehicle battery. An electronic processor correlates the internal impedance to a temperature forecast received via a connected service, and predicts an end of life of the vehicle battery based upon the correlation. The electronic processor then notifies a user of the predicted end of life via a connected service.

In yet another embodiment, a different method of predicting an end of life of a vehicle battery is provided. In this embodiment a connected system of the vehicle transmits a determined internal impedance of the vehicle battery to a central computing system. The central computing system then correlates the transmitted internal impedance to a temperature forecast and predicts an end of life of the vehicle battery. The central computing system then notifies a user of the predicted end of life.

Other aspects of and various embodiments will become apparent by consideration of the detailed description and accompanying drawings.

### BRIEF DESCRIPTION OF THE DRAWINGS

FIG. 1 depicts a block diagram of a system incorporating a battery end of life predictor with a connected service.

FIG. 2 depicts a schematic diagram of a battery end of life prediction system with connected service.

FIG. 3 depicts a flow chart describing an algorithm for predicting the failure of a vehicle battery.

### DETAILED DESCRIPTION

Before any embodiments are explained in detail, it is to be understood that embodiments described and illustrated are not limited in their application to the details of construction and the arrangement of components set forth in the following description or illustrated in the following drawings. The embodiments described and illustrated may be practiced or carried out in various ways and other embodiments are possible.

Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. As used within this document, the word “or” may mean inclusive or. As a non-limiting example, if it were stated in this document that “item Z may comprise element A or B,” this may be interpreted to disclose an item Z comprising only element A, an item Z comprising only element B, as well as an item Z comprising elements A and B.

A plurality of hardware and software-based devices, as well as a plurality of different structural components may be used to implement various embodiments. In addition, embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the invention may be implemented in software (for example, stored on non-transitory computer-readable medium) executable by one or more electronic processors. “Control units,” “controllers,” and similar devices described in the specification can include one or more electronic processors, one or more application specific integrated circuits (ASICs), one or more memory modules including non-transitory computer-readable medium, one or more input/output interfaces, and various links and connections (for example, a system bus) connecting the various components.

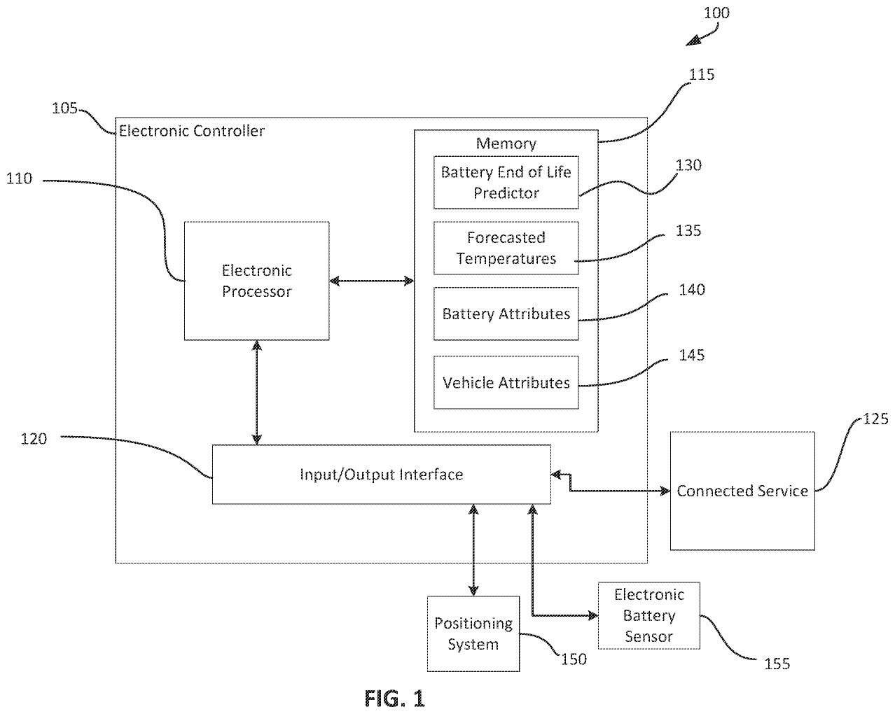

FIG. 1 depicts a block diagram of a system 100 incorporating a battery end of life predictor with connected services. In the example shown, the system 100 includes an electronic controller 105 in communication with a connected service 125 (described in more detail below), a positioning system 150, and an electronic battery sensor 155. The electronic controller 105 may include a plurality of electrical and electronic components that provide power, operation control, and protection to the components and modules within the electronic controller 105. In the example illustrated, the electronic controller 105 may include, among other things, an electronic processor 110 (such as a programmable electronic microprocessor, microcontroller, distributed or local multi-processor, or similar device), a memory 115 (for example, non-transitory, machine readable memory), an input/output interface 120. Input/output interface 120 may be communicatively connected to connected service 125, positioning system 150, and electronic battery sensor 155. Connected service 125 includes a remote computer-implemented service, for example, a weather information service, automatic emergency call service, a road condition service, a traffic condition service, a wrong-way driver service, a vehicle diagnostic service, a vehicle telemetry service, or other similar service that may be implemented using cloud computing resources, satellite and cellular network connectivity, and other suitable resources that support mobility services. Connected service 125 may also be configured to facilitate the sending or receiving of electronic communications (for example, SMS messages, email messages, and the like) via the electronic controller 105. Positioning system 150 may include a GPS processor and transceiver through which global positioning information may be obtained. The positioning system 150 may also include other hardware and components to support other positioning techniques, for example, cell signal triangulation. Electronic battery sensor 155 includes a battery sensor that in some embodiments is constructed and arranged to sense attributes of a vehicle battery, for example, voltage, charge, and/or current of the battery.

The electronic processor 110 is communicatively connected to the memory 115 and the input/output interface 120. The input/output interface 120 is communicatively connected to a connected service 125. During, for example, execution of the battery end of life predictor 130, the input/output interface 120 communicates requests from the electronic processor 110 to connected service 125. The input/output interface 120 also communicates service of those requests by connected service 125 to the electronic processor 110. The positioning system 150 may be constructed and arranged to deliver a geographical location to the electronic processor 110 via the input/output interface 120. Electronic battery sensor 155 senses battery attributes 140 and delivers them to the electronic processor 110 via the input/output interface 120. In some embodiments, the memory 115 includes forecasted temperatures 135, obtained via connected service 125 and stored in memory 115 by electronic processor 110, containing at least one forecasted temperature for a geographical location at a future date or time. The memory 115 may also include battery attributes 140, for example, battery capacity, battery state of health, battery voltage, battery state of charge, battery model, battery size, or other battery attributes of a vehicle battery. In some embodiments, the memory 115 includes vehicle attributes 145. The vehicle attributes 145, may include, for example vehicle make, vehicle model, vehicle transmission type, cranking requirements, and so forth.

In most embodiments, the electronic processor 110 is housed in a vehicle. However, with sufficient network connectivity, the electronic processor 110 may be part of a remote computing system accessible over a network and communicate with the vehicle. Similarly, the memory 115 may be volatile or non-volatile memory, or a combination thereof and may also be local accessible or remotely accessible over a network via a cloud storage service or data center. The electronic processor 110, in coordination with the memory 115 the input/output interface 120, the positioning system 150, connected service 125, and electronic battery sensor 155 may thus be configured to implement, among other things, the methods described herein. Functions described herein as being performed by the battery end of life predictor 130 should be understood to, at least in some embodiments, be performed by the electronic processor 110 executing the battery end of life predictor 130.

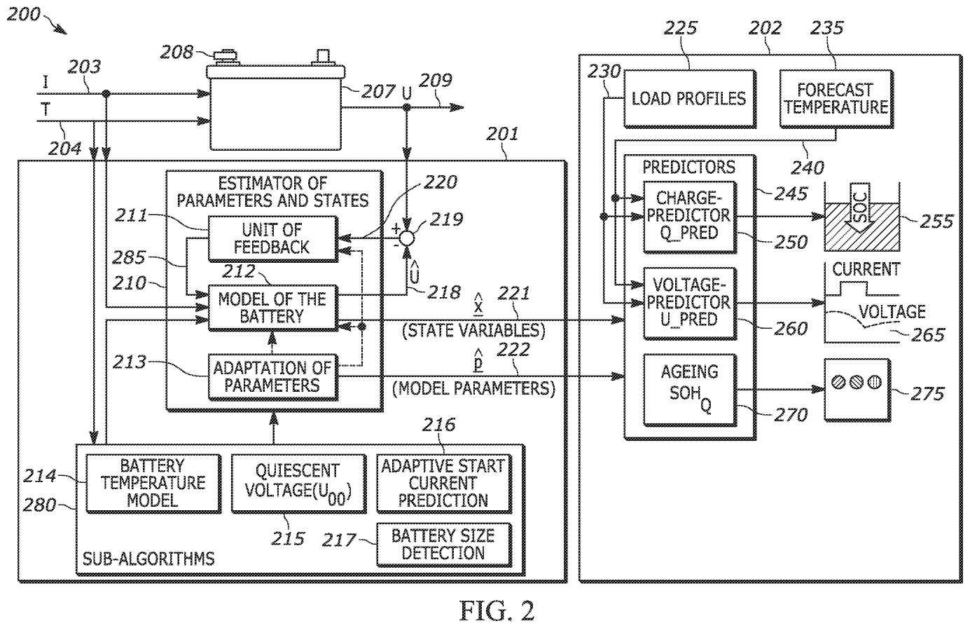

FIG. 2 depicts a schematic diagram of a battery end of life prediction system with connected services. In the example shown, a battery parameter estimator 201 is in communication with a battery state predictor 202. Both battery parameter estimator 201 and battery state predictor 202 may be executed by the system described in FIG. 1. In the example shown in FIG. 2, the battery parameter estimator 201 and battery state predictor 202 in combination perform functionality associated with the battery end of life predictor 130. The battery parameter estimator 201 is constructed and arranged to receive a current input 203 as well as a temperature input 204 and may produce battery state variables 221 and battery model parameters 222 as output. A vehicle battery 207 which includes an electronic battery sensor 208 also provides a measured battery voltage 209 as input to the battery parameter estimator 201. The battery parameter estimator 201 comprises primary functions block 210 that executes a feedback block 211, battery model block 212, and adaption block 213 to produce the battery state variables 221 as output. The primary functions block 210 also produces the battery model parameters 222 as output for the battery state predictor 202.

Sub-algorithms block 280 is configured to assist the primary functions block 210 by providing analysis of runtime variables tied to operating values of the vehicle battery 207. Sub-algorithms block 280 takes temperature input 204 and produces a battery temperature model 214, a quiescent battery voltage 215, a start current prediction 216, and battery size detection 217 as outputs to the primary functions block 210. The production of a battery temperature model 214 by sub-algorithms block 280 may be supported by any necessary sensing devices connected to the vehicle battery 207, for example, to the electronic battery sensor 208. Battery temperature model 214 is a model of the battery operating in the present temperature, or an assumed temperature. Battery temperature model 214 provides a mathematical model how a present or assumed temperature affects present operation of the vehicle battery 207. The present or assumed temperature is delivered to sub-algorithms block 280 as temperature input 204 for the creation of or to update of battery temperature model 214. Quiescent battery voltage 215 may be a zero-load, open circuit voltage, or Vo measurement for battery voltage, or a deduced version of the same if a measurement is not available. The measurement may be made via electronic battery sensor 208. Start current prediction 216 be generated by a subroutine for predicting the amount of current that will be drawn from the battery upon starting the vehicle based at least upon vehicle features and connected loads. Battery size detection 217 may be a detected battery size, determined in sub-algorithms block 280 on the basis of present operating values of the vehicle battery 207.

In the embodiment shown, a measured battery voltage 209 is compared to an estimated battery voltage 218 computed by the battery model block 212 using battery voltage comparator 219 to produce a voltage difference 220. The measured battery voltage 209 is used in a feedback loop within the primary functions block 210 formed by the feedback block 211 and the battery model block 212. The voltage difference 220 is delivered by the battery voltage comparator 219 to the feedback block 211. Feedback block 211 is in communication with the battery model block 212 and the adaption block 213 and processes the voltage difference 220 in light of a current battery model determined by the battery model block 212 and battery adaption parameters determined by the adaption block 213. The feedback block 211 provides feedback information 285 resulting from the analysis of the voltage difference 220 as input to the battery model block 212 for the purpose of determining an updated battery model.

Battery model block 212 receives feedback information 285 from the feedback block 211, information from sub-algorithms block 280 as input, as well as current input 203. Based upon these inputs, battery model block 212 and produces a model of the vehicle battery 207 in the form of battery state variables 221, for example, battery voltage output, amperage output, or charge. When considered in light of input conditions as well as the changing parameters of the aging battery, battery state variables 221 may be used to determine the future behavior of the battery. Therefore, battery state variables 221 are output from the battery model block 212 of the primary functions block 210 and received as an input by the battery state predictor 202.

Also in the embodiment shown, adaption block 213 is in communication with the feedback block 211 and the battery model block 212. The adaption block 213 determines parameters relevant to battery state predictor 202 for application during a battery state prediction process. The adaption block 213 determines these parameters on the basis of data provided by sub-algorithms block 280 including battery temperature model 214, quiescent battery voltage 215, start current prediction 216, and battery size detection 217. Data provided to the adaption block 213 may be used by the sub-algorithms block 280 to deduce battery model parameters 222 that may change over the lifetime of the vehicle battery 207, for example, internal resistance and battery capacity that may be applied to battery state variables 221 in battery state predictor 202. Battery model parameters 222 are output from the battery model block 212 of the primary functions block 210 and received as an input by the battery state predictor 202.

Battery aspects predictor block 245 receives battery state variables 221 and battery model parameters 222 as inputs and predicts future aspects of the vehicle battery 207 via a battery aspects predictor block 245. Battery state predictor 202 includes a load profiles block 225, a forecast temperature block 235, and a battery aspects predictor block 245. Forecast temperature block 235 may obtain a temperature forecast via connected service 125 and deliver it to battery aspects predictor block 245 as forecasted temperature 240. Load profiles block 225 may provide a load profile 230 to the battery aspects predictor block 245. Load profile 230 provided by the load profiles block 225 may be preloaded into memory 115 or received in response to a request made to connected service 125. Both forecasted temperature 240 and load profile 230 may be used as inputs by charge predictor block 250 and voltage predictor block 260 in predicting a future state of charge 255 and future voltage 265 of the vehicle battery 207. State of health block 270 may determine a future state of health of the battery 275 based at least upon battery state variables 221 and battery model parameters 222. State of health block 270 may also contain routines for monitoring, storing, and accessing stored events affecting the health of the vehicle battery 207.

Battery state predictor 202 uses the future state of charge 255, future voltage 265, and future state of health of the battery 275 to determine whether the vehicle battery 207 will be able to supply a required amperage or voltage to a starter motor of the vehicle (not shown) at the time for which forecasted temperature 240 was given. Battery state predictor 202 also determines whether a predicted failure of the vehicle battery 207 to supply the required amperage or voltage is due to a poor state of health of the vehicle battery 207. For example, battery state predictor 202 may determine that forecasted temperature 240 may cause a drop in the future voltage 265 or future state of charge 255 of the vehicle battery 207. The battery state predictor 202 may also determine that vehicle battery 207 is consequently unable to provide the required amperage or voltage to a starter motor, and additionally that the future state of health of the battery 275 is degraded to a point foreclosing the vehicle battery 207 from being charged to overcome this predicted failure.

In the case of a predicted end of life of the vehicle battery 207 as described above, the battery state predictor 202 may notify a key user or owner of the vehicle via vehicle lights, or vehicle systems as described herein, or via a connected service of the predicted end of life of the vehicle battery 207. The notification of the predicted failure may contain or be accompanied by a suggestion that the vehicle battery 207 be replaced before the date or time of the predicted failure.

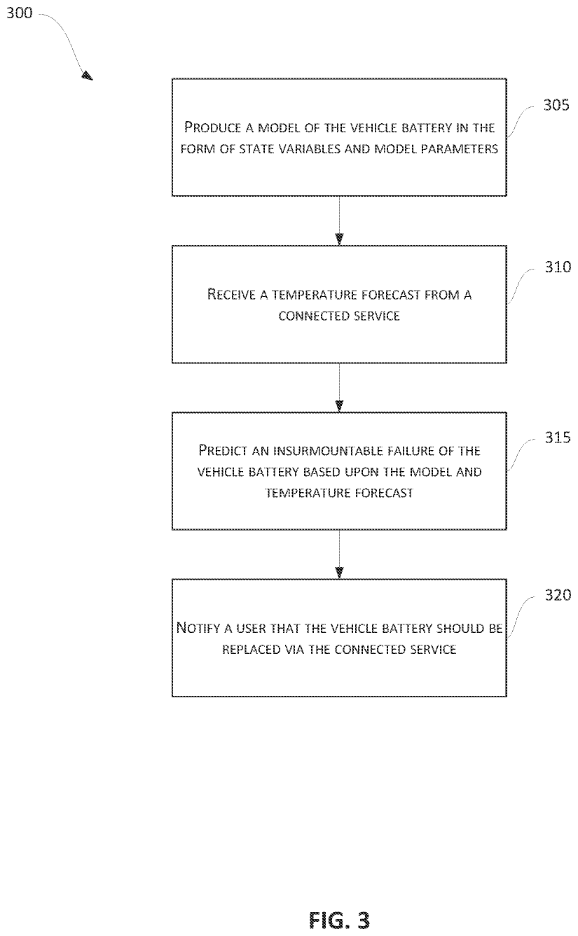

FIG. 3 depicts a flowchart 300 on an example method of predicting the failure of (or end of life of) a vehicle battery 207 executed by the electronic processor 110. The flowchart 300 is described with respect to the system 100 of FIG. 1. However, in some embodiments, the flowchart 300 is implemented by other systems.

At block 305, the electronic processor 110 produces a model of the vehicle battery 207 in the form of battery state variables 221 and battery model parameters 222 as described above. The model may include a state of health of the vehicle battery 207 based upon attributes of the vehicle battery 207, for example, internal impedance. In some embodiments, electronic battery sensor 155, 208 measures or estimates the internal impedance of a vehicle battery 207. In other embodiments, the internal impedance of the battery may be determined by the electronic processor 110 based on measurements provided by the electronic battery sensor 155, 208. For example, the electronic processor 110 may receive voltage and current measurements from the electronic battery sensor 155, 208 and use of Kirchhoff s voltage law and circuit simplification to solve for internal impedance. Values used in producing the model of the vehicle battery 207 may be stored and retrieved from the memory 115, and may also be shared directly between the electronic battery sensor 155, 208 and the electronic processor 110 via input/output interface 120 without the use of memory 115.

At block 310, the electronic processor 110 submits a request for a forecasted temperature 240 to a central computing system, for example, a cloud computing service via connected service 125. The temperature forecast request may be accompanied by informational context for the request, for example, a geographical location to which the forecasted temperature 240 should pertain, a time frame for which the forecasted temperature 240 is requested, or a frequency per unit time of the requested forecasted temperature 240 (e.g. a request for two temperature forecasts per hour, over twenty-four hours per day, over three days beginning on May 19, 2020, for Detroit, Mich.). A forecasted temperature 240 may be submitted to a central computing system on a periodic basis or in response to a trigger event. For example, trigger events include an internal impedance of a vehicle's battery reaching a threshold, a charge of a vehicle's battery reaching a certain threshold, the voltage output of a vehicle's battery reaching a certain threshold, or the current output of a vehicle's battery reaching a certain threshold. In some cases, the forecasted temperature 240 transmitted by the central computing system to the vehicle comprises more than one forecasted temperature 240 that are saved in aggregate within memory 115 as forecasted temperatures 135. Filtering criterion may also be communicated with the submitted request for a forecasted temperature 240. The central computing system adheres to the filtering request by, for example, transmitting more than one forecasted temperature 240, including only temperatures at and below twenty degrees Fahrenheit within a particular time span. If the temperature forecast request lacks informational context, the returned forecasted temperature 240 may be based upon default informational context. For example, if a time span is not specified, a forecasted temperature 240 may be given for a default period of a week starting from the time or day that the request was submitted. As another example, if no frequency per unit of time is specified, the forecasted temperature 240 may be given for three points in time for each day forecasted. As yet another example, if no frequency per unit of time is specified, a minimum or maximum temperature forecasted during a particular time period for each day forecasted may be used as the forecasted temperature 240. If no location is specified for the temperature forecast, the current location of the vehicle as provided by positioning system 150, which may be positioned on the vehicle, may be used.

At block 315, the electronic processor 110 executes a predictive algorithm to predict whether the vehicle battery 207 will die due to a future temperature change and should be replaced on the basis of the battery state of health in light of a temperature forecast selected from the plurality of forecasted temperatures 135. In some cases, the predictive algorithm produces a predictive battery impedance curve, and correlates the internal impedance of the battery to the forecasted temperature 240 in order to predict whether the vehicle battery 207 will be able to provide a required cranking amperage or voltage, to a starter motor, at the forecasted temperature 240. In other cases, the predictive impedance curve is used to determine a threshold temperature at which the vehicle battery 207 will die prior to receiving a forecasted temperature 240.

At block 320, the electronic processor 110 notifies a user of a predicted end of life of the vehicle battery 207 via the connected service 125. Notifying the user comprises illuminating a heads up display, warning light, or display in a manner indicative of the predicted future failure. In some cases, illuminating a heads up display or display comprises elucidating the details of the predicted failure, for example, the fact of an increased internal impedance of the vehicle battery 207, predicted insufficient cranking amperage or voltage, or a forecasted, detrimental drop in temperature. In some cases, is the notifications also be delivered to a user via SMS, email, or another messaging system. Sometimes, the notification also contains a suggestion that the vehicle battery 207 be replaced within a specified or generalized time frame.

As noted above, in block 310 flowchart 300, the temperature forecast is received by electronic processor 110. The temperature forecast is received by the electronic processor 110 via connected service 125 without making a request for a temperature. For example, a central computing service or weather center may periodically provide connected service 125 with a temperature forecast pertaining to the vehicle's geographical location without receiving a request for any such forecast. In response, connected service 125 relays this forecast to electronic processor 110. In some cases, temperature forecasts are intelligently provided by a central computing service or weather center, without prompting, well in advance of a notable weather event that may affect battery temperature such as a polar vortex. The electronic processor 110 either immediately uses a received forecasted temperature 240, or stores it in memory 115 for access at a later time. When the forecasted temp 240 is stored in memory, stored forecasted temperature 240 is updated or replaced in memory 115 when a new pertinent forecast is received. As discussed in further detail above, the received forecasted temperature 240 sometimes includes more than one forecasted temperature 240 for a particular location, at a particular time of day, on a particular date. As also discussed above, the electronic processor 110 may use each forecasted temperature 240 within the forecasted temperatures 135 in predicting an end of life of a vehicle battery 207. In some cases, the electronic processor 110 uses a group average or maximum or minimum values of a selection of more than one forecasted temperature 240 from the plurality of forecasted temperatures 135 in making the prediction. In other cases, the electronic processor 110 may select a single forecasted temperature 240 from the plurality of forecasted temperatures 135 to use in predicting an end of life of a vehicle battery 207.

In other embodiments, the notification delivered to a key user or owner of the vehicle may be generated by the vehicle including the vehicle battery 207 to which the notification pertains, or the notification may be generated by a central computing service, for example, by a cloud computing service. In the former case, the notification may be generated by the vehicle because the prediction of an end of life of a vehicle battery 207 was performed primarily onboard the vehicle. In the latter case the central computing service generates the notification, for example, because the prediction of an end of life of a vehicle battery 207 was performed primarily at the central computing service. Specifically, a central computing system may receive a vehicle battery model produced by a vehicle using onboard vehicle systems and perform the function of the battery state predictor 202 entirely remote from the vehicle. The central computing system can store the vehicle battery model and perform the functions of the battery state predictor 202 against the model even if the vehicle is completely turned off or not producing new or updated vehicle battery models. The central computing system can therefore notify a key user or owner of the vehicle of a predicted an end of life based on a days-old vehicle battery model in light of a new forecasted temperature 240, even without a recently updated vehicle battery model.

In other embodiments, a starter motor is constructed and arranged to crank an internal combustion engine of a vehicle upon start up. In order to crank the vehicle engine, the starter motor requires a certain amount of current or voltage to be drawn from a vehicle battery 207. If the starter motor is unable to draw a required amount of current or voltage from the vehicle battery 207, the vehicle will not start. It may be the case that the vehicle battery 207 is unable to provide the required amount of current or voltage to the starter motor because the vehicle battery 207 is at a state of discharge wherein it is physically impossible to provide the required amount of current or voltage to the starter motor. In some cases, the failure of the vehicle battery 207 to provide the required amount of current or voltage to the starter motor can be remedied by charging the battery. To that end, if the battery is in a state of health that supports recharging the vehicle battery 207 back to a level of charge at which the required amount of current or voltage may be provided by the vehicle battery 207 to the starter motor, the vehicle will notify the user of a need to recharge the battery via systems, for example, a heads-up display, an indicator light, an audio cue, and SMS message, and email or some other means of notification. However, if the battery will not support a sufficient recharge, the failure is identified as an end of life, and the battery must be replaced. If the battery is in a state of health that does not support recharging the vehicle battery 207 back to such a level of charge, the vehicle notifies the user that the vehicle battery 207 is dead and must be replaced before the vehicle can be started again.

In other embodiments, a drop in battery temperature reduces the maximum amperage or voltage that a vehicle battery 207 can produce under load. In such cases, this temperature-based reduction in producible amperage or voltage to a vehicle battery 207 causes the vehicle battery 207 to fail to provide an amount of amperage or voltage to a starter motor of a vehicle required for cranking the vehicle engine. In such cases, an end of life of a battery is predicted, and a user is notified ahead of time that the battery should be changed to avoid such a failure. To that end, an electronic battery sensor 155, 208 may be used in concert with a battery parameter estimator 201 and a battery state predictor 202 to predict a temperature at which a vehicle battery 207 will fail to provide the required amperage or voltage for driving a starter motor of the vehicle to crank a vehicle engine. The battery parameter estimator 201 monitors and analyzes vehicle battery data measured by the electronic battery sensor 155, 208 to provide an up-to-date vehicle battery model when the vehicle is actively drawing power from the battery. The vehicle battery model may include, for example, a present state of health, a present state of function, a present temperature, a battery style, a battery type, a battery size, a present load, and a variance between measured vehicle battery values provided by the electronic battery sensor 155, 208 and estimated vehicle battery values determined by the battery parameter estimator 201. The battery state predictor 202 receives the vehicle battery model from the battery parameter estimator 201 in the form of battery state variables 221 and battery model parameters 222. The battery state predictor 202 subjects the model of the vehicle battery 207 to at least one load profile 230 and determines a temperature at which the vehicle battery 207 will fail. This may occur by way of the battery state estimator subjecting the battery model to a one or more load profiles 230 over a spectrum of temperatures using a battery state predictor 202 algorithm (described above). In some embodiments, this process occurs for each load profile 230. A probability of future failure regarding common load profiles is determined in light of a temperature forecast obtained by the battery state predictor 202, or in preparation for the receipt of such a temperature forecast, via the vehicle's connected service 125. If the probability of failure reaches a predetermined threshold for a forecasted temperature 240, the battery state predictor 202 notifies a key user via at least one of the vehicle systems, for example, the connected service 125 of the vehicle. To predict an end of life of the vehicle battery 207, the battery state predictor 202 factors a future state of health of the battery 275 into each probability of an end of life determination, the future state of health of the battery 275 being predicted by the battery state predictor 202 for the date or time of each forecasted temperature 240. An end of life is predicted by the battery state predictor 202 on a date or at a time of a forecasted temperature 240 if it is predicted that the vehicle battery 207 will be incapable of storing sufficient charge to successful crank the vehicle engine via a starter motor at that time. If an end of life is predicted, the battery state predictor 202 notifies a key user or vehicle owner that the battery is predicted to fail and should be replaced. This notification includes a date or time by which the battery should be replaced.

In other embodiments, a vehicle's connected service 125 provides a forecasted temperature 240 for a particular geographical location. Forecasted temperature 240 may comprise a plurality of temperature forecasts, forecasted with a predetermined frequency, over a span of time. In some cases, a time span for the forecast is predetermined. For example, the temperature forecast is given for a default period of a three days starting from 1 A.M. on the day that the request was submitted. As another example, if no frequency per unit of time is specified, the forecasted temperature 240 may be given for each hour of each day forecasted. By default the forecasted temperature 240 may be for the current geographical location of the vehicle, as determined by GPS. In some cases, the location for the forecasted temperature 240 is for another location, for example, a planned destination of the vehicle. Additionally, the forecasted temperature 240 may be for a relatively pinpointed location, for example, the geographical location of a GPS unit, a township, or a relatively expansive location, for example, a state. The forecasted temperature 240 may also be an average of multiple temperature forecasts. As a non-limiting example, if a forecasted temperature 240 is sought for the entire state via a vehicle's connected service 125, the returned forecasted temperature 240 may be an average of forecasted temperatures 135 for the state on a particular date at a particular time. The forecasted temperature 240 may also simply be a high or low temperature for a particular day in a particular region or at a particular location.

In other embodiments, an electronic battery sensor 155, and 208 is used in combination with a number of estimator algorithms to produce a vehicle battery model. This vehicle battery model may come in the form of a state-space model described by a plurality of battery state variables 221. A future battery state condition for example, a future state of charge 255, a future state of function (not shown in figures), or a future state of health of the battery 275 is determined based upon the battery state variables 221. A state of function may also be determined by the electronic battery sensor 155, and 208 and estimator algorithms, and refer to the ability of the vehicle battery 207 to perform a task for example, providing sufficient amperage or voltage to a vehicle starter motor to start the vehicle.

In other embodiments, amperage or voltage required by a starter motor of a vehicle in order to successfully crank the vehicle engine is not defined, particular amount of amperage or voltage. In some cases, a battery state predictor 202 predicts whether the amount of amperage or voltage deliverable by a vehicle battery 207 is likely to drive a starter motor to successfully start the vehicle engine. The battery state predictor 202 is configured to make this prediction by being constructed and arranged to receive a sensed voltage, charge, or current of a vehicle battery 207 from an electronic battery sensor 155, and 208. Additionally, the battery state predictor 202 may be configured to make this prediction by being constructed and arranged to receive an estimated voltage, charge, or current reading from the battery parameter estimator 201. The battery state predictor 202 receives a number of cranking likelihood amperage or voltage thresholds for the particular configuration of the vehicle from a battery parameter estimator 201. These cranking likelihood amperage or voltage thresholds are determined by the battery parameter estimator 201 or be loaded into memory 115 accessible by an electronic controller 105 as predetermined values. The cranking likelihood amperage or voltage thresholds may also be organized on a spectrum from a first threshold, indicating that a failure to crank is extremely likely, to thresholds indicating that a failure to crank is not very likely. Having received the sensed or estimated voltage, charge, or current, the battery state predictor 202 predicts future values for the sensed or estimated voltage, charge, or current of the vehicle battery 207 by correlating the sensed or estimate voltage, charge, or current to the plurality of cranking likelihood thresholds. This correlation allows the battery state predictor 202 to determine the likelihood of a failure. The prediction process may take place entirely onboard a vehicle. When an end of life is predicted, the battery state predictor 202 uses a connected service to notify a key user or owner of the vehicle of the predicted an end of life.

In other embodiments, a starter motor of a vehicle must reach a required speed before successfully cranking the engine of the vehicle. In some cases, the speed of the starter motor is proportionally related to the voltage supplied to the starter motor. In such cases, a battery state predictor 202 is configured to predict a future voltage 265 supplied by the vehicle battery 207 based upon a vehicle battery model. Owing to the fact that the voltage and amperage supplied by a vehicle battery 207 may be closely related, a prediction of future voltage 265 supplied may also be used by a battery state predictor 202 in light of a forecasted temperature 240 to determine an end of life of the vehicle battery 207 for the purpose of cranking a vehicle engine with a starter motor, according to the methods described herein.

In other embodiments, a central computing system, for example, a cloud computing service may receive a state of health for a vehicle battery 207 from a vehicle. This state of health is accompanied by an internal impedance of the vehicle battery 207, and a location of the vehicle including the vehicle battery 207. The central computing system may use the state of health of the battery as well as the internal impedance of the vehicle battery 207 to predict a future state of health of the battery 275 of the battery as well as a future internal impedance of the vehicle battery 207. The central computing system may thus predict an end of life of the vehicle battery 207 based upon the future state of health of the battery 275, the future internal impedance of the vehicle battery 207, and a forecasted temperature 240 for the location of the vehicle including the vehicle battery 207, or the location of the vehicle battery 207 itself. In still other embodiments, the central computing system receives a model for the vehicle battery 207 in the form of battery state variables 221 and battery model parameters 222 from a battery parameter estimator 201. The central computing system predicts an end of life of the vehicle battery 207 by determining a future form of the vehicle battery model and correlating it to a forecasted temperature 240 at the location of the vehicle battery 207. The correlation allows a central computing system to act as a battery state predictor 202 and to determine the likelihood of an end of life of the vehicle battery 207. The central computing system either uses a connected service 125 to notify a key user or owner of the vehicle of the predicted end of life of the vehicle battery 207, or communicates the notification directly to the key user or owner of the vehicle via separate communication means.

Various embodiments, features, and advantages are set forth in the following claims.

What is claimed is:

1. A vehicle battery failure estimator comprising;
an electronic processor configured to:
produce a model of a vehicle battery as battery state variables and battery model parameters;
receive a temperature forecast from a connected service;
predict an end of life of the vehicle battery based upon the model of the vehicle battery and the temperature forecast;
based on the predicted end of life, generate a notification that the vehicle battery should be replaced; and
transmit the notification, via the connected service, to a user.

2. The vehicle battery failure estimator of claim 1 wherein producing the model of the vehicle battery includes determining an internal impedance of the vehicle battery.

3. The vehicle battery failure estimator of claim 2 wherein determining the internal impedance for the vehicle battery includes
measuring a quiescent voltage of the vehicle battery;
measuring a voltage of the vehicle battery under load;
measuring an amperage output of the vehicle battery under load; and
solving for the internal impedance of the vehicle battery based upon the quiescent voltage, the voltage under load, and the amperage output under load.

4. The vehicle battery failure estimator of claim 1 wherein notifying the user that the battery should be replaced includes notifying the user of time by which the battery should be replaced.

5. The vehicle battery failure estimator of claim 1 further comprising notifying the user that the battery should be recharged.

6. The vehicle battery failure estimator of claim 1 wherein receiving the temperature forecast includes
communicating a request for the temperature forecast, a geographical location for which the temperature forecast is requested, as well as a predetermined span of time for which the temperature forecast is requested; and
receiving a response to the request.

7. The vehicle battery failure estimator of claim 1 wherein the temperature forecast includes a plurality of forecasted temperatures.

8. The vehicle battery failure estimator of claim 1 wherein notifying the user that the vehicle battery should be replaced comprises sending the user one of an SMS message or an email via the connected service.

9. A method comprising:
determining, by an electronic battery sensor, an internal impedance for a vehicle battery;
receiving, by an electronic processor, a temperature forecast comprising a plurality of forecasted temperatures from a connected service;
predicting, by an electronic processor, an end of life of the vehicle battery based upon a correlation of the internal impedance and the temperature forecast; and
notifying, by an electronic processor, a user of the predicted end of life via a connected service,
wherein the vehicle battery is constructed and arranged to deliver a required amount of cranking amperage to a starter motor of a vehicle, and
wherein the predicted end of life manifests as the vehicle battery becoming incapable of maintaining enough charge to deliver the required amount of cranking amperage to the starter motor at a forecasted temperature selected from the plurality of forecasted temperatures.

10. The method of claim 9, wherein notifying the user of the end of life includes illuminating an indicator light or a display in a manner that indicates the end of life.

11. The method of claim 9, wherein notifying the user of the end of life includes sending the user one of an SMS or an email that indicates the an end of life.

12. The method of claim 11, wherein notifying the user of the end of life further comprises a message suggesting to the user that the battery should be replaced within specified time span.

13. The method of claim 9, wherein determining the internal impedance for the vehicle battery includes
measuring, by the electronic battery sensor, a quiescent voltage of the vehicle battery;
measuring, by the electronic battery sensor, a voltage of the vehicle battery under load;
measuring, by the electronic battery sensor, an amperage output of the vehicle battery under load; and
solving, by the electronic battery sensor, for the internal impedance of the vehicle battery based upon the quiescent voltage, the voltage under load, and the amperage output under load.

14. The method of claim 9, wherein receiving the temperature forecast includes
communicating a request for the temperature forecast, a geographical location for which the temperature forecast is requested, as well as a predetermined span of time for which the temperature forecast is requested; and
receiving a response to the request.

15. The method of claim 9, wherein the plurality of forecasted temperatures comprises daily forecasted average temperatures for each day in a span of three days.

16. The method of claim 9, wherein the plurality of forecasted temperatures comprises a collection of lowest reasonably possible temperatures at a geographical location and over a time span for which the temperature forecast is requested.

17. The method of claim 9, wherein predicting an end of life of the vehicle battery further comprises predicting an increase in the cranking amperage required to be delivered to the starter motor in light of the plurality of forecasted temperatures due to a probability of mechanical drag on an internal combustion engine of the vehicle.

18. A method comprising:
determining, by an electronic battery sensor, an internal impedance for a vehicle battery;
transmitting, by a connected system of a vehicle, the determined internal impedance to a central computing system;
correlating, by the central computing system, the transmitted internal impedance to a temperature forecast comprising a plurality of forecasted temperatures;
predicting, by the central computing system, an end of life of the vehicle battery based upon a correlation of the internal impedance and the temperature forecast; and
notifying, by the central computing system, a user of the predicted end of life,
wherein the vehicle battery is constructed and arranged to deliver a required amount of cranking amperage to a starter motor of the vehicle, and
wherein the predicted end of life is in the form of the vehicle battery becoming incapable of maintaining enough charge to deliver a required amount of cranking amperage to the starter motor at a forecasted temperature selected from the plurality of forecasted temperatures.

19. The method of claim 18, wherein notifying the user of the predicted an end of life includes sending the user one of an SMS or an email notification that indicates the predicted end of life and a message suggesting to the user that the battery should be replaced within specified time span.

20. The method of claim 19, wherein the notification is sent after the vehicle is turned off.
